(19) United States
(12) Patent Application Publication
(10) Pub. No.: US 2012/0033509 A1
(43) Pub. Date: Feb. 9, 2012

(54) Memory data reading and writing technique

(76) Inventors: Paolo Menegoli, San Jose, CA (US); Fabio Alessio Marino, San Jose, CA (US)

(21) Appl. No.: 12/927,674

(22) Filed: Nov. 22, 2010

Related U.S. Application Data
(60) Provisional application No. 61/401,093, filed on Aug. 9, 2010.

(51) Int. Cl. G11C 7/00; G11C 8/08

(52) U.S. Cl. 365/189.14; 365/203

(57) ABSTRACT

A novel circuit for reading data in solid state memory cells is presented. It can be used for any type of memory cell array but more specifically it is particularly suited for volatile memories like SRAM and DRAM. It is based on sensing the current in the ground line of the memory cell when the data is being read. This eliminates the need for detecting large voltage swings on the bit line resulting in large delays or complex sense amplification circuits. It offers the advantages of being very small in silicon area, very fast and very efficient. The read and write static noise margins are increased with respect to conventional techniques. The current can be amplified and converted to a voltage signal by a transimpedance amplifier ac coupled to a sense resistor on the ground line. The signal can be successively latched. The same technique can be used to detect when the writing of a cell has been successfully carried out.

The present application claims priority from U.S. Provisional Patent Application N.61/401,093 for “Memory Data Reading Technique” filed on Aug. 9, 2010.

### BACKGROUND OF THE INVENTION

1. Field of the Invention

The present invention is in the field of semiconductor. The present invention further relates to semiconductor memory circuits. The present invention further relates to the field of volatile memory cells. The implementation is not limited to a specific technology, and applies to either the invention as an individual component or to inclusion of the present invention within larger systems which may be combined into larger integrated circuits.

2. Brief Description of Related Art

The general performance of a semiconductor memory depends largely on the reading and writing speed, and reliability. In particular, the ability to read the stored data without losing or deteriorating the digital information is vital to the solid state data storage device. Volatile memories like SRAM (Static Random Access Memory) and DRAM (Dynamic Random Access Memory) mainly use sense amplifiers to read the stored data. Once the memory cell whose data needs to be read is selected, the access transistors (or single transistor in the case of a DRAM) in the cell make the voltage or voltages stored in the cell available to be detected by the sense amplifier circuit.

Typically the sense amplifier senses the voltage on the bit lines, but this limits the reading speed because depending on the resistance and capacitance associated with the bit line, the voltage swing needed to have a reliable sensing may be considerably slow. In the case of SRAMs the most utilized version of sense amplifier is basically a latch made of two cross coupled inverters like the SRAM memory circuit itself.

FIG. 1 is a detailed circuit schematic of one of the most common sense amplifiers used in SRAM memories. It represents a full complementary positive feedback sense amplifier. The transistors M1, M2, M3 and M4 are connected as cross coupled inverter and represent the latch, M5 and M6 are the access transistors to the bit line and M7 is the enable transistor. This configuration is commonly referred to as “voltage mode sense amplifier” since the signal to be amplified is a voltage signal.

When the reading of a memory cell is requested, the sense amplifier of FIG. 1 is enabled by applying positive voltage to the signal SE. The Bit Lines BL and B̅L̅ bar are pre-charged at Vdd/2 and the amplifier senses whether the voltage of the BL and B̅L̅ bar signals toggles in one direction of the other.

The bit line is pre-charged at Vdd/2 so that when the access transistor is closed, any voltage mismatch on the two bit lines between the stored voltage and Vdd/2 toggles the sense amplifier in the direction to confirm the stored value. Clearly any mechanism of reading the data stored in the cell always somewhat perturbs the cell itself.

One of the most important parameters in memory cells manufacturing is the SNM (Static Noise Margin) which is a figure of merit of the ability for the memory cell to be read without either reading the wrong bit or degrading the stored value. This is of course very much related to the sense amplifier type and circuit topology and in more general terms to the memory reading approach utilized.

Differential approaches have also been used to minimize the effects of noise during the sensing of the data. In that case the selected memory cell data is read by comparing the value with a reference cell. This is often done in current mode where the current generated by the selected cell is compared with the current from a reference cell. This eliminates any common mode voltage and current noise. The current mode approach assumes that the signal to be amplified is a current signal rather than a voltage signal.

However many other schemes of memory sense amplifiers have been proposed in the past. Forbes (U.S. Pat. No. 6,288,575) describes a pseudo-differential current sense amplifier with hysteresis that builds on many previous attempts to read the data in current rather than in voltage so as to limit the required swing.

Similarly Tzartzanis (U.S. Pat. No. 7,075,842) describes a differential current mode sense amplifier used for memory devices. Forbes (U.S. Pat. No. 7,221,605) describes a switched capacitor implementation of a differential sense amplifier whose inputs are ac coupled to the bit lines. Waller et al. (U.S. Pat. No. 7,486,563) describes a similar method.

Wilcox (U.S. Pat. No. 6,944,084) describes a method to measure the power consumption by means of an amplifier coupled to a power plane sense resistor so that the current in the memory cells can be measured and eventually regulated. However it does not address the memory data reading. In Wilcox the sense resistor is connected to the whole memory system to somehow control the current consumption of the device as similarly done in many other applications.

Ehrenreich et al. (U.S. Pat. No. 7,808,856) describes a means for reducing the memory cell leakage current by introducing virtual ground lines for arrays of memory cells connected to the ground line in order to effectively regulate the overall supply line applied to the memory cells. Similarly Zampaglione et al. (U.S. Pat. No. 7,684,262) describes a means for controlling the leakage current of the memory cell by applying a voltage to the cell by modulating the voltage of the virtual ground lines. Again Sachdev et al. (U.S. Pat. No. 7,372,721) proposes a switch between the virtual ground lines and ground to reduce the leakage current during data retention. Zhang et al (U.S. Pat. No. 5,986,923) proposes a similar circuit to improve the read/write stability of a memory cell thus reducing the SNM.

However all these techniques do not address the problem of improving on the speed and power consumption of the memory cell data reading. Furthermore they have several shortcomings. The mismatches and offsets generated by normal and expected process variations in presence of large arrays of memory cells do not reliably determine the values of current with respect to the reference cell. The reading speed of these techniques is always limited by the charge associated with the capacitance of the nodes within either the memory cell or the multiplexer employed to access the cell, or the sense amplifier.

It is therefore a purpose of the present invention to describe a novel memory data reading approach that combines the advantages of higher speed, high and adjustable static and dynamic noise margin, low power consumption and reliable data detection.

### SUMMARY OF THE INVENTION

It is an objective of the present invention to provide a solid state memory reading approach that improves on the prior art data reading techniques, by detecting the polarity of the stored datum by means of sensing the current in the ground (most negative) terminal of the memory cell.

It is another objective of the present invention to provide a memory reading method that improves on the reading speed without degrading the static noise margin, by adaptively or dynamically adjusting the value of a sense resistor.

It is another objective of the present invention to provide a memory data writing approach that includes a feedback signal to sense the current perturbation that occurs in the cell during the writing phase. This feedback signal indicates when the writing of the cell has been completed. This improves on the writing speed of the memory cell and potentially also on the current consumption during the writing phase.

It is another objective of the present invention to provide a method for reducing the power applied to the memory cell by limiting the current with a sense resistor. The resistor itself provides a series feedback approach, but furthermore a current into the resistor may dynamically change the voltage applied to the memory cells in order to reduce its leakage current and the overall power consumption.

It is another objective of the present invention to provide a method for improving on the testing of the memory cells by monitoring the voltage drop on a sense resistor coupled to a group of memory cells. The detection of a defective memory cell presenting much higher leakage current can be achieved in a faster way by reading the sense resistor voltage drop and comparing it with an expected value.

The present invention describes a memory reading circuit that is based on sensing the current flowing in the cell during the reading operation. The current is sensed by means of a sense resistor on the ground line of each group of memory cells associated with a specific sense amplifier.

With reference to an SRAM, a reading operation is initiated by pre-charging the word line to a voltage (that most typically can be the supply voltage) and by detecting whether the forcing of a 1 into the latch (memory cell) via the access transistor causes the latch to toggle into the opposite polarity. If and when that tends to occur a current starts flowing into the ground terminal of the cell. The current will flow into the ground terminal as long as a 1 is forced into the latch and the latch was previously storing a 0.

In alternative the pre-charging of the word line could be eliminated, therefore reducing the power dissipated, by means of reading the residual voltage present at the word line when the memory cell reading is requested. This value is typically either low (close to ground) or high (close to the supply voltage) and by knowing its polarity and detecting the presence of a current perturbation or lack thereof, the polarity of the datum stored in the cell can be univocally determined.

By coupling a series sense resistor to the ground terminal of the cell, the current signal is converted into voltage and a fast sense amplifier coupled to the sense resistor detects the presence of current. If no current is detected by the sense amplifier within a reasonable time frame, it can be concluded that the access transistor is confirming the existing logic state in the cell.

In the case that a current is detected, and therefore the stored datum polarity is known, as soon as a certain current level is detected, a signal is fed back to the word line or to the bit line control circuit to stop the reading procedure before an accidental undesired writing occurs (destroying the stored datum).

The ground sense resistor is connected to a group of memory cells, as long as only one of these cells is read at any particular time. Today's sense amplifiers are already connected in similar configurations because they are coupled to the bit line and only one cell at the time is read within the same bit line. The sense resistor value has to be scaled such that the writing operation of the cell is allowed.

The value of the sense resistor is very important to increase the static noise margin of the cell and to define the speed of the read and write operation. The higher the sense resistor value, the faster is the read operation and the slower the write operation. The static noise margin can be significantly increased by dynamically changing the value of the sense resistor depending on whether the memory cell is being written or read. In fact a transistor can be placed in parallel to the sense resistor (or to a portion of the sense resistor) to lower its total resistance during the writing operation.

A small voltage on the sense resistor can be amplified with a large bandwidth amplifier or the sense resistor may be part of the feedback network of a trans-impedance amplifier. A trans-impedance amplifier (TIA) converts a small current into voltage. The TIA can be very fast. Therefore the need for much higher voltage swings of conventional solutions is no longer present, allowing a much faster dynamic response.

In alternative a capacitive coupling between the sense resistor and an amplifier may provide the necessary signal level to respond adequately swiftly to the presence of ground current in the cell being read. The voltage drop on the ground of the memory cells not being read has to be adequate in order not to disturb their stored data.

As previously mentioned the sense resistor is connected to a group of memory cells and possibly as many as possible to reduce the silicon area overhead. This connection to the negative terminal of many memory cells causes the connection to the sense resistor to be capacitive possibly resulting in slow voltage conversion of the current flowing in the resistor. This limits the value of the sense resistor to low values and it may be more advantageous to include the resistor as part of a trans-impedance amplifier.

Furthermore it is important to note that according to the proposed circuit topology what is detected is not a DC current level, rather a current perturbation which typically is a fast event. Such fast event should not be erroneously exchanged for a supply line perturbation. The sensing technique has to be immune to the power line variations. It is difficult to obtain high PSRR (Power Supply Rejection Ratio) if the sense amplifier does not adopt a differential approach.

Therefore it may be advantageous to utilize a differential sense amplifier that compares the voltage or current signal coming from the memory cell being read to the signal coming from an equivalent reference cell. This way any noise coming from other undesired sources is common mode to the sense amplifier and the static noise margin is increased significantly.

It is desirable to enable the reference memory cell at the same time that the cell being read is enabled in order to minimize any dynamic unbalance in the circuit. The reference memory cell has to store a known datum.

Furthermore the presented approach does not require any pre-charging of the bit line to half supply voltage since the detection mechanism is totally different. This simplifies enormously the overhead circuits around the memory banks.

The sense resistor can also be used to limit the cell power dissipation during the write operation. In addition and more generally, the power applied to the memory cell can be controlled by limiting the current with a sense resistor. The resistor itself provides a series feedback limiting approach, but by dynamically changing a current into the resistor, or by directly applying a voltage at the negative terminal of the memory cells, the overall voltage applied to the memory cells can be modulated in order to reduce the memory cell leakage current and the overall power consumption.

The requirements for the sense amplifier are to have high speed, but also to occupy minimum silicon area and consume a small amount of power. It can be implemented as in FIG. 3. FIG. 3 shows an example of a detailed circuit schematic of a general memory cell 5 of an SRAM, and an embodiment of the sense amplifier 6. The blocks 5 and 6 are coupled through a sense resistor R2 and a capacitor C1. The capacitor C1 performs an AC coupling allowing small voltage levels to be detected by the amplifier 6. The amplifier 6 is enabled by the transistors M13 and M14 at the same time or immediately following the pre-charge of the bit line BL.

The transistor M14 performs also a reset function of the latch following the first stage of the amplifier 6. As soon as the amplifier 6 is enabled, its input, represented by the gate voltage of the transistor M17 is biased at the Vgs voltage needed to maintain a given current in M17. As soon as this voltage is increased by current flowing in C1, M17 drives its drain voltage low and toggles the following latch formed by the transistors M19-M22.

The sense amplifier 6 detects a fast voltage change across the sense resistor R2. The toggling of the latch in the block 6 is interpreted as the reading of a “0” held in the memory cell 5. The lack of toggling of the sense amplifier 6 is interpreted as the reading of a “1” stored in the memory cell 5. The interpretation can be as validly done by inverting the read data.

When the transistor M13 is turned off the sense amplifier consumes zero current. When it is turned on, the settling of the stage is very fast, certainly faster than the settling of the bit line. The implementation of FIG. 3 offers the advantages of being fast, consuming very little current in operation and utilizing a small silicon area.

When the output of the sense amplifier is coupled to drive circuit of either the word line driver or the bit line driver, a feedback mechanism can be included according to which the reading of the cell is terminated as soon as the sensed current has reached a predetermined threshold so as not to lose the store datum and toggle the memory element.

As is clear to those skilled in the art, this basic system can be implemented in many specific ways, and the above descriptions are not meant to designate a specific implementation.

Similarly, this basic technique has been described with particular attention to the Static Random Access Memory applications, but it can also be implemented more generally for the data reading of other types of memory cells like DRAM and non volatile memories (Flash and EEPROM).

Furthermore the described technology has been mainly described with special emphasis on the reading operation, but the same approach can be utilized for the writing operation offering the benefit of higher write speed cycles. In fact, the current in the sense resistor and the voltage associated with it may indicate whether the writing cycle has being carried out successfully.

### BRIEF DESCRIPTION OF THE DRAWINGS

Further details of the present invention are explained with the help of the attached drawings in which:

FIG. 1 shows a general circuit implementation of a prior art of a sense amplifier of an SRAM;

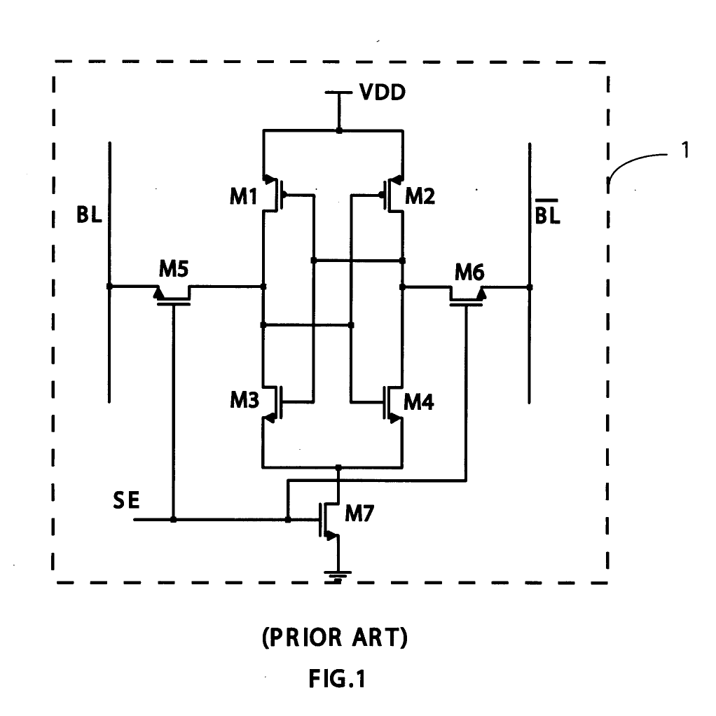

FIG. 2 shows a block diagram of the section of a solid state memory and the sense amplifier according to the preferred embodiment of the present invention;

FIG. 3 shows a detailed circuit implementation of an SRAM memory cell, the sense amplifier and the network coupling the memory cell to the sense amplifier;

FIG. 4 shows a general block diagram of a section of a solid state memory reading and writing in accordance with another preferred embodiment of the present invention.

FIG. 5 shows a general block diagram of a section of a solid state memory reading and writing in accordance with another preferred embodiment of the present invention where a differential sensing approach is presented.

### DETAILED DESCRIPTION OF SPECIFIC EMBODIMENTS

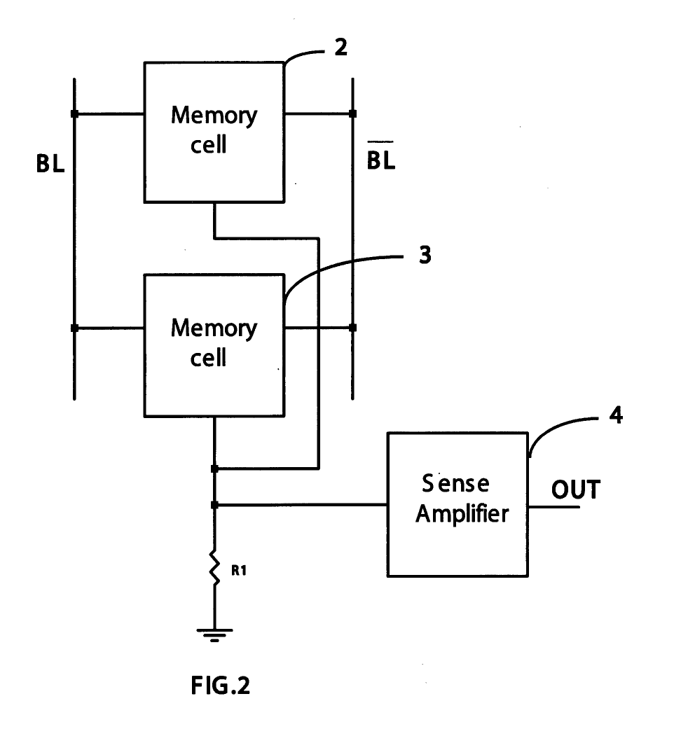

### A FIG. 2

FIG. 2 is depicting the general block diagram of the read/write section of a solid state memory device in accordance with the preferred embodiment of the present invention. In the drawing only two memory cells, blocks 2 and 3, are showed for simplicity, but many more are normally connected to the same bit lines and sense amplifier.

The main topological difference between FIG. 2 and the prior art implementations is that the sensing of the logic state is performed on the ground line and not on the bit lines. The bit lines sensing offers the advantage that they are already used to access both the specified memory cell and the sense amplifier, therefore it simplifies the connection between the memory cells and the sense amplifier, but it has the main disadvantage of being slow because the bit lines are typically very capacitive since many access transistors are connected to them.

The common ground connection of the memory cells to the ground pad is present in conventional SRAM and DRAM memory circuits and it does not represent a larger silicon area usage. By adding a simple resistor R1 of adequate value in series to the negative terminal of the cells connected to the same bit lines, the current flowing in the cells is converted into voltage. The memory cells typically are subject to perturbation when the cells are written and read. This perturbation causes a fast increase of voltage across the terminals of the resistor R1.

The voltage of the negative terminal of the memory cells not being read or written connected to the same sense resistor is raised by the voltage drop on the ground of the memory cell being read or written. Therefore this negative terminal voltage increase has to be small enough not to disturb their stored data.

Nowadays generally the memory cells do not consume large quantities of power. In fact generally the only current flowing in the sense resistor when no cell is being written or read is exclusively the leakage current of the cell. These currents are extremely low. But when a cell is written or read the current increases significantly.

This rapid increase of current can be directly detected by the sense amplifier or be converted into voltage by the sense resistor and detected by the amplifier. The sense amplifier 4 can be implemented in many ways. It can be also implemented as a trans-impedance amplifier where the sense resistor R1 could be part of the amplifier feedback network. The value of the resistor R1 is very important to determine the overall gain of the circuit and to effectively increase the Static Noise Margin of the cell.

The circuit of FIG. 2 can also be implemented with only one bit line. The pre-charge voltage of the bit line does not have to be exactly half the supply voltage, but it can simply be the supply voltage and this represents another advantage of the present invention because it simplifies the bit line drive circuit with respect to the more traditional circuit topology.

The sense amplifier 4 can also be utilized to detect the writing of the datum in the memory cell. When the cells is written, the cell current perturbation is detected and when such ground current peak has decreased back to low levels the cell has been successfully written. This is the case when the logic state being written is different from the one previously held. If the logic state is the same, no current or only a very small current is detected and after some time it can be assumed that the cell has been successfully written.

Furthermore the reading of the voltage across the sense resistor R1 can be exploited to test the memory integrated circuit. By comparing the voltage in a specific condition with the expected value, a defective memory cell can easily be detected without testing every memory cell individually.

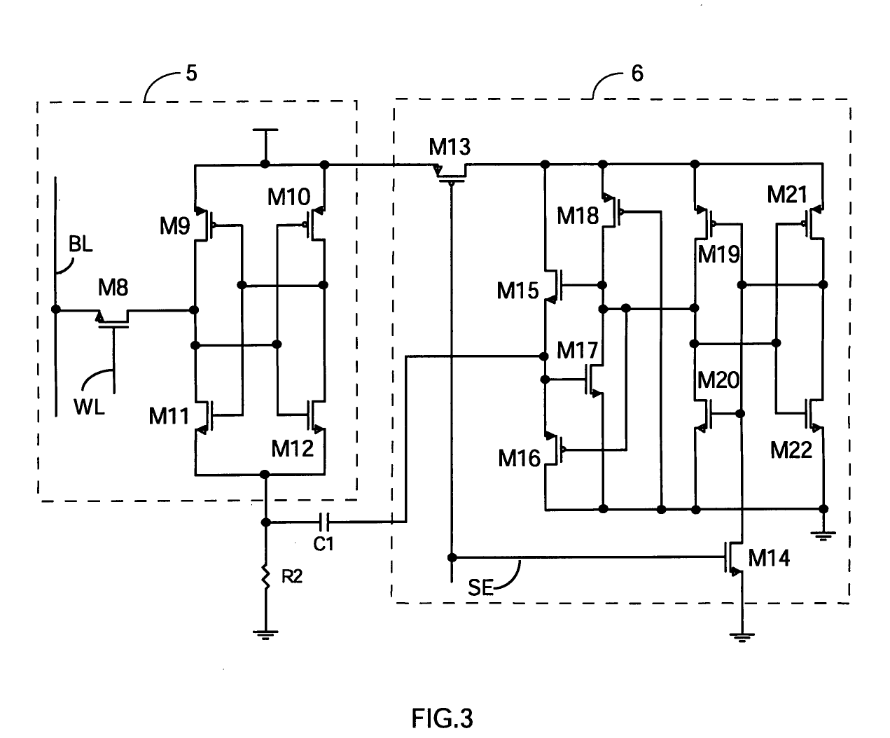

### B FIG. 3

FIG. 3 shows a detailed circuit schematic of a general memory cell 5 of an SRAM, and an embodiment of the sense amplifier 6. The blocks 5 and 6 are coupled through a sense resistor R2 and a capacitor C1. The capacitor C1 performs an AC coupling allowing small voltage levels to be detected by the amplifier 6. The amplifier 6 is enabled by the transistors M13 and M14 at the same time that the bit line BL is pre-charged.

The transistor M14 performs also a reset function of the latch following the first stage of the amplifier 6. As soon as the amplifier 6 is enabled, its input, represented by the gate voltage of the transistor M17 is biased at the Vgs voltage required to maintain a given current in M17. As soon as this voltage is increased by current flowing in C1, M17 drives its drain voltage low and toggles the following latch formed by the transistors M19-M22.

The sense amplifier 6 detects a fast voltage change across the sense resistor R2. The toggling of the latch in the circuit 6 is interpreted as the reading of a “0” value held in the memory cell 5. The lack of toggling of the sense amplifier 6 is interpreted as the reading of a “1” stored in the memory cell 5. The interpretation can be as validly done by inverting the read data.

When the transistor M13 is turned off the sense amplifier consumes zero current. When it is turned on, the settling of the stage is very fast, certainly faster than the settling of the bit line. The implementation of FIG. 3 offers the advantages of being fast, consuming very little current when operating and utilizing a small silicon area.

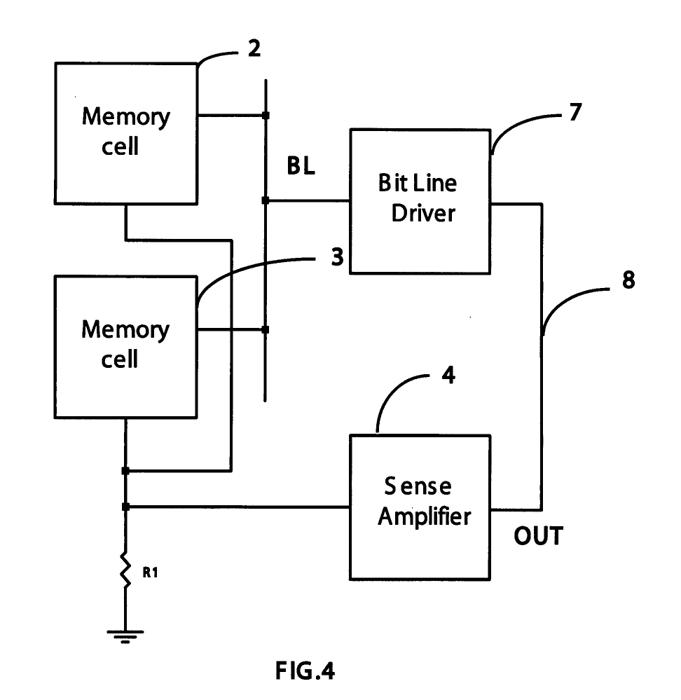

### C FIG. 4

When the sense amplifier detects the reading of a “0”, the access to the memory cell can be disabled before the held logic state is lost by means of a feedback circuit. In alternative the read logic state can be confirmed by changing the bit line as shown in FIG. 4. FIG. 4 is similar to FIG. 2, but one output signal from the sense amplifier 4 can be used in closed loop configuration to stop the forcing of the logic state in the cell. This technique allows a faster reading cycle and a current consumption reduction during the memory reading.

FIG. 4 shows that the feedback signal 8 is fed to the word line driver circuit to turn off the memory cell access transistor. An equivalent function can be obtained by having the feedback signal 8 fed back to the bit line driver to toggle the bit line, confirming the read signal. This is particularly advantageous for the DRAM memory cells where every read cycle is essentially a refresh cycle as well and where any degradation of the stored data has to be re-integrated.

The value of the sense resistor R1 is very important because a high value makes the reading faster and an accidental undesired writing much more difficult, but the desired cell writing also slower. Therefore a transistor could be added in parallel to the sense resistor R1 or to a portion of R1 to lower its resistance value during the writing operation.

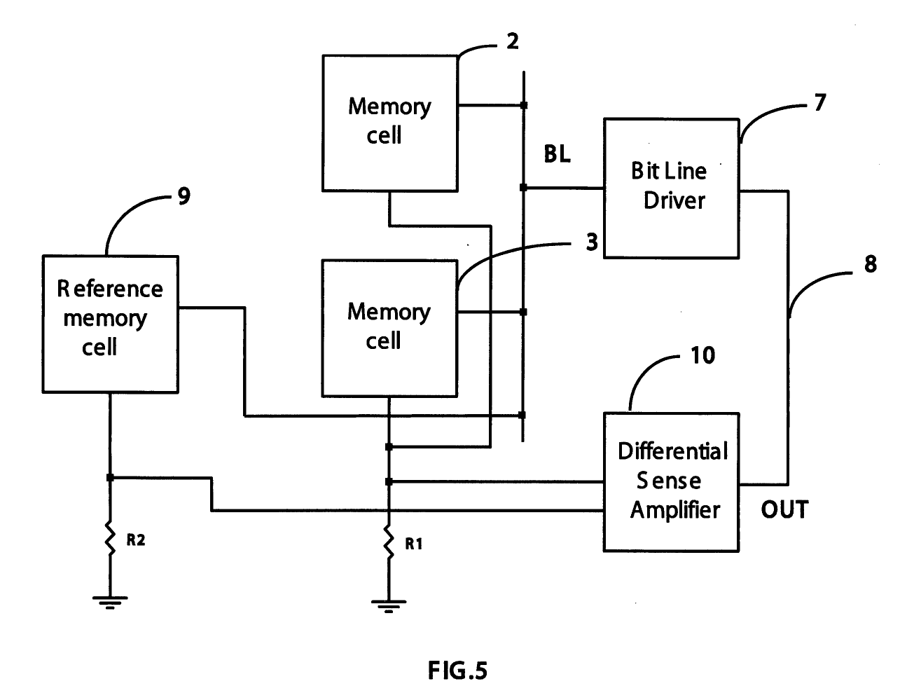

### D FIG. 5

FIG. 5 is very similar to FIG. 4. The main difference is that a reference memory cell 9 has been added and the sense amplifier 10 is a differential amplifier that compares the voltage across the resistor R1 with the voltage across the resistor R2. It should be noted that the ground of R1 and R2 is the same in order to avoid any possible ground noise affecting the data reading operation.

Since what is detected is not a DC current level, rather a current perturbation which typically is a fast event, the sensing technique has to be immune to the power line variations and or to any other source of possible noise. For instance it is difficult to obtain high PSRR (Power Supply Rejection Ratio) if the sensing scheme is not differential.

Therefore it may be advantageous to utilize a differential sense amplifier 10 that compares the voltage or current signal coming from the memory cell being read to the signal coming from an equivalent reference cell 9. This way any noise coming from any other undesired source is common mode to the sense amplifier and the static noise margin is increased significantly.

Although the present invention has been described above with particularity, this was merely to teach one of ordinary skill in the art how to make and use the invention. Many additional modifications will fall within the scope of the invention. Thus, the scope of the invention is defined by the claims which immediately follow.

What is claimed is:

1. A circuit for writing and reading the data stored in solid state memory device comprising:
a sense resistor coupled between the negative terminal of a plurality of memory cells and the ground terminal of said circuit, and
an amplifier coupled to said sense resistor;
wherein the current flowing in said sense resistor generates a voltage signal that is amplified by said amplifier, and
whereby the detection of presence and amplitude of said current flowing in said sense resistor determines the logic state of the datum stored in said solid state memory device.

2. The circuit of claim 1 wherein said amplifier coupled to said sense resistor is coupled by means of a series capacitor;
wherein the first terminal of said series capacitor is directly coupled to the positive terminal of said sense resistor and to said negative terminal of a plurality of memory cells and the second terminal of said series capacitor is directly coupled to the input terminal of said amplifier.

3. The circuit of claim 1 wherein said sense resistor is replaced by a transistor;
wherein the drain terminal of said transistor is coupled to the positive terminal of said sense resistor and to said negative terminal of a plurality of memory cells;
wherein the source terminal of said transistor is coupled to said ground terminal of said circuit;
wherein the gate terminal of said transistor is coupled to a control circuit, and whereby said control circuit modulates the voltage of said gate terminal in response to a reading or writing command of said solid state memory device.

4. The circuit of claim 1 wherein a transistor is coupled to said sense resistor;
wherein the drain of said transistor is coupled to the positive terminal of said sense resistor and to said negative terminal of a plurality of memory cells;
wherein the source terminal of said transistor is coupled to the ground terminal of said circuit;
wherein the gate terminal of said transistor is coupled to a control circuit, and whereby said control circuit modulates the voltage of said gate terminal in response to a reading or writing command of said solid state memory device.

5. The circuit of claim 1 wherein said sense resistor is replaced by two or more resistors;
wherein the drain of a transistor is coupled to one or more of said resistors;
wherein the source terminal of said transistor is coupled to the ground terminal of said circuit;
wherein the gate terminal of said transistor is coupled to a control circuit, and whereby said control circuit modulates the voltage of said gate terminal in response to a reading or writing command of said solid state memory device.

6. The solid state memory device of claim 1 wherein said circuit is comprising a feedback signal coupled to the output terminal of said amplifier and to a driver circuit, and
wherein said driver circuit is coupled to a bit line or to a word line of said solid state memory device.

7. A method for reading the data stored in a solid state memory device comprising:
pre-charging the bit line of a memory cell of said solid state memory device to a first voltage;
enabling at least one access transistor of said memory cell by applying a second voltage to the word line associated to said memory cell;
enabling a sense amplifier associated to said memory cell and coupled to a sense resistor in series to the negative terminal of a plurality of memory cells, and
detecting the presence and amplitude of the current flowing in said negative terminal of a plurality of memory cells by means of said sense resistor and of said amplifier;
whereby the detection of presence and amplitude of said current determines the logic state of the datum stored in said solid state memory device.

8. The method of claim 7 wherein said amplifier coupled to said sense resistor is coupled by means of a series capacitor and,
wherein the first terminal of said series capacitor is directly coupled to the positive terminal of said sense resistor and to said negative terminal of a plurality of memory cells and the second terminal of said series capacitor is directly coupled to the input terminal of said amplifier.

9. The method of claim 7 wherein said sense resistor is replaced by a transistor;
wherein the drain terminal of said transistor is coupled to the positive terminal of said sense resistor and to said negative terminal of a plurality of memory cells;
wherein the source terminal of said transistor is coupled to the ground terminal of said solid state memory device;
wherein the gate terminal of said transistor is coupled to a control circuit, and whereby said control circuit modulates the voltage of said gate terminal in response to a reading or writing command of said solid state memory device.

10. The method of claim 7 wherein a transistor is coupled to said sense resistor;
wherein the drain of said transistor is coupled to the positive terminal of said sense resistor and said negative terminal of a plurality of memory cells;
wherein the source terminal of said transistor is coupled to the ground terminal of said solid state memory device;
wherein the gate terminal of said transistor is coupled to a control circuit, and whereby said control circuit modulates the voltage of said gate terminal in response to a reading or writing command of said solid state memory device.

11. The method of claim 7 wherein said sense resistor is replaced by two or more resistors,
wherein the drain of a transistor is coupled to one or more of said resistors;
wherein the source terminal of said transistor is coupled to the ground terminal of said circuit;
wherein the gate terminal of said transistor is coupled to a control circuit, and whereby said control circuit modulates the voltage of said gate terminal in response to a reading or writing command of said solid state memory device.

12. The method of claim 7 wherein said solid state memory device is comprising a feedback signal coupled to the output terminal of said amplifier and to a driver circuit, and
wherein said driver circuit is coupled to a bit line or to a word line of said solid state memory device.

13. The method of claim 7 wherein said sense amplifier is used to write data in said memory cell.

14. The method of claim 7 wherein said sense resistor is used to limit the current consumption of said plurality of memory cells.

15. The method of claim 7 wherein said sense amplifier is used to accelerate the testing of said solid state-memory device.
